(19) United States
(12) Patent Application Publication
(10) Pub. No.: US 2025/0385651 A1
(43) Pub. Date: Dec. 18, 2025

(54) JAMMER RESILIENT INDUCTOR-LESS LOW-NOISE AMPLIFIER FOR HIGH FREQUENCIES

(71) Applicant: QUALCOMM Incorporated, San Diego, CA (US)

(72) Inventors: Marco VIGILANTE, San Diego, CA (US); Ahmed ABBAS MOHAMED HELMY, San Diego, CA (US); Youssef Osama HASSAN, Irvine, CA (US); Jian KANG, San Diego, CA (US); Aleksandar Miodrag TASIC, San Diego, CA (US)

(21) Appl. No.: 18/746,838

(22) Filed: Jun. 18, 2024

(51) Int. Cl. H03F 3/24; H03F 1/26; H04B 1/40

(52) U.S. Cl. CPC H03F 3/245; H03F 1/26; H04B 1/40; H03F 2200/294; H03F 2200/451

(57) ABSTRACT

A system for wireless communications. The system includes a low-noise amplifier (LNA). The LNA includes an inverter, a radio frequency (RF) feedback circuit coupled between an output of the inverter and an input of the inverter to provide an RF feedback loop, and a coupling capacitor coupled between an input of the LNA and the input of the inverter, wherein the coupling capacitor is located outside of the RF feedback loop. The system also includes a bias circuit coupled between the output of the inverter and the input of the inverter.

### FIELD

Aspects of the present disclosure relate generally to wireless communications, and, more particularly, to low-noise amplifiers.

### BACKGROUND

A wireless device (e.g., smart phone) may transmit and receive radio frequency (RF) signals in one or more wireless networks (e.g., a long-term evolution (LTE) network, a fifth generation (5G) network, a wireless local area network (WLAN), etc.). To receive RF signals, the wireless device includes one or more antennas and one or more low-noise amplifiers (LNAs) configured to amplify RF signals received by the one or more antennas.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a system for wireless communications. The system includes a low-noise amplifier (LNA). The LNA includes an inverter, a radio frequency (RF) feedback circuit coupled between an output of the inverter and an input of the inverter to provide an RF feedback loop, and a coupling capacitor coupled between an input of the LNA and the input of the inverter, wherein the coupling capacitor is located outside of the RF feedback loop. The system also includes a bias circuit coupled between the output of the inverter and the input of the inverter.

A second aspect relates to a system for wireless communications. The system includes a low-noise amplifier (LNA). The LNA includes an inverter including a p-type metal-oxide-semiconductor (PMOS) transistor and an n-type metal-oxide-semiconductor (NMOS) transistor, a first radio frequency (RF) feedback circuit coupled between an output of the inverter and a gate of the PMOS transistor to provide a first RF feedback loop, and a second RF feedback circuit coupled between the output of the inverter and a gate of the NMOS transistor to provide a second RF feedback loop. The LNA also includes a first coupling capacitor coupled between an input of the LNA and the gate of the PMOS transistor, wherein the first coupling capacitor is located outside of the first RF feedback loop, and a second coupling capacitor coupled between the input of the LNA and the gate of the NMOS transistor, wherein the first coupling capacitor is located outside of the second RF feedback loop. The system also includes a bias circuit coupled between the output of the inverter and the gate of the PMOS transistor or coupled between the output of the inverter and the gate of the NMOS transistor.

### BRIEF DESCRIPTION OF THE DRAWINGS

FIG. 1A shows an example of a system including a low-noise amplifier (LNA) and a receive circuit according to certain aspects of the present disclosure.

FIG. 1B shows an example of the system of FIG. 1A in which the LNA and the receive circuit are integrated on a chip according to certain aspects of the present disclosure.

FIG. 2 shows an exemplary implementation of the receive circuit of FIGS. 1A and 1B according to aspects of the present disclosure according to certain aspects of the present disclosure.

FIG. 3 shows an example of an inductor-less LNA according to certain aspects of the present disclosure.

FIG. 4A shows an example of an RF feedback loop in the LNA of FIG. 3 according to certain aspects of the present disclosure.

FIG. 4B shows an example of a bias loop in the LNA of FIG. 3 according to certain aspects of the present disclosure.

FIG. 4C shows an example of a positive feedback loop in the LNA of FIG. 3 according to certain aspects of the present disclosure.

FIG. 5 shows an example of an LNA with improved low frequency stability according to certain aspects of the present disclosure.

FIG. 6A shows another example of an LNA with improved low frequency stability according to certain aspects of the present disclosure.

FIG. 6B shows yet another example of an LNA with improved low frequency stability according to certain aspects of the present disclosure.

FIG. 7A shows an example of the exemplary LNA of FIG. 5 coupled to the receive circuit according to certain aspects of the present disclosure.

FIG. 7B shows an example of the exemplary LNA of FIG. 6A coupled to the receive circuit according to certain aspects of the present disclosure.

FIG. 7C shows an example of the exemplary LNA of FIG. 6B coupled to the receive circuit according to certain aspects of the present disclosure.

FIG. 8 is a diagram of an environment including an electronic device that includes a transceiver according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

A wireless device may include one or more low-noise amplifiers (LNAs) configured to amplify radio frequency (RF) signals received by one or more antennas. The wireless device may be implemented as any suitable wireless device, such as as a cellular or mobile phone, a gaming device, a navigation device, a media device, a laptop computer, a desktop computer, a tablet computer, a server computer, a network-attached storage (NAS) device, a smart appliance, a vehicle-based communication system, an Internet of Things (IoT) device, a sensor or security device, an asset tracker, and so forth.

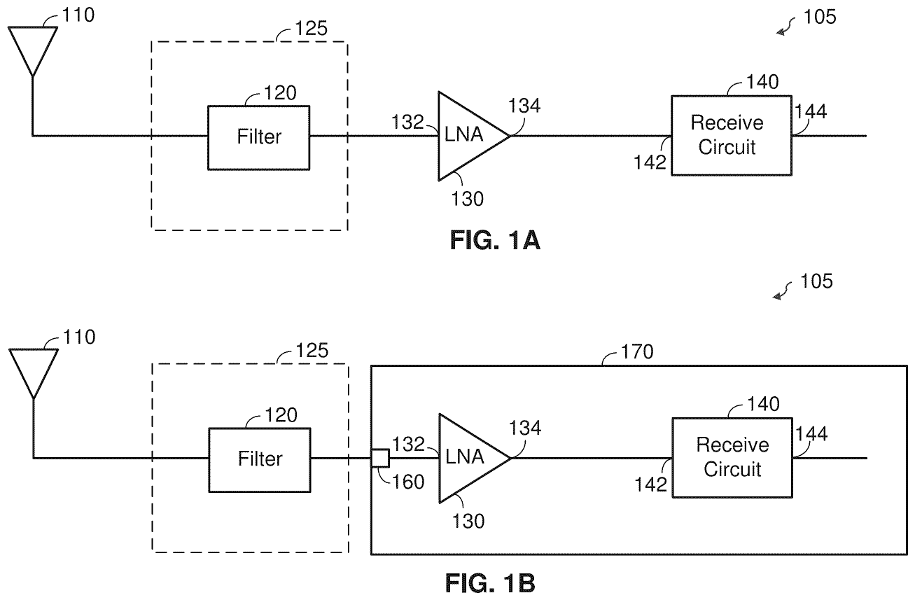

FIG. 1A shows an example of a system 105 including an LNA 130 according to certain aspects. The system 105 may be included in the wireless device for receiving wireless signals (e.g., radio frequency (RF) signals in the GHz frequency range). In the example shown in FIG. 1A, the system 105 also includes an antenna 110, a front-end circuit 125 (also referred to an RF front-end (RFFE) circuit or module), and a receive circuit 140. The receive circuit 140 may be included in a transceiver. Although one antenna 110, one front-end circuit 125, and one LNA 130 are shown in FIG. 1A, it is to be appreciated that the wireless device may include multiple antennas (e.g., arranged in an array), multiple front-end circuits, and/or multiple LNAs.

In the example in FIG. 1A, the LNA 130 has an input 132 and an output 134, in which the front-end circuit 125 is coupled between the antenna 110 and the input 132 of the LNA 130. The receive circuit 140 has an input 142 and an output 144. The input 142 of the receive circuit 140 is coupled to the output 134 of the LNA 130. The output 144 of the receive circuit 140 may be coupled to a baseband processor (also referred to as a modem), an intermediate frequency (IF) circuit, or another type of circuit.

In one example, the front-end circuit 125 may be configured to condition an RF signal from the antenna 110 before the RF signal is input to the LNA 130. For example, the front-end circuit 125 may include a filter 120 and/or one or more other circuits. In certain aspects, the filter 120 may be a bandpass filter configured to pass an RF signal received from the antenna 110 within a desired frequency band (i.e., pass band) to the LNA 130 while filtering out signals (e.g., interfering signals) outside the desired frequency band. The front-end circuit 125 may include one or more other circuits (not shown in FIG. 1A) such as an additional LNA, a duplexer, a diplexer, one or more switches, and the like. In some implementations, the front-end circuit 125 may be omitted with the input 132 of the LNA 130 coupled to the antenna 110 without the front-end circuit 125.

The LNA 130 is configured to receive the RF signal from the front-end circuit 125 at the input 132, amplify the RF signal, and output the amplified RF signal at the output 134.

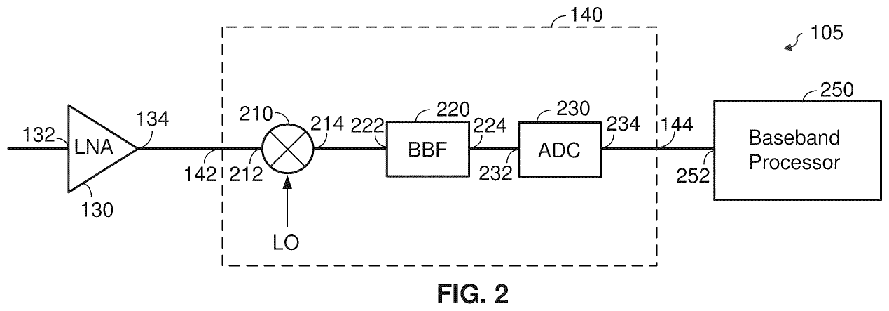

The receive circuit 140 is configured to receive the RF signal from the LNA 130 at the input 142, convert the RF signal into a baseband signal or an intermediate frequency (IF) signal, and output the baseband signal or the IF signal at the output 144. For example, the receive circuit 140 may include a mixer (shown in FIG. 2) configured to mix the RF signal with a local oscillator signal to frequency downconvert the RF signal to obtain the baseband signal or the IF signal. The receive circuit 140 may also include one or more amplifiers, one or more filters (e.g., a baseband filter), or any combination thereof. The receive circuit 140 and the LNA 130 may be integrated on the same chip (i.e., die) or separate chips.

For the example where the receive circuit 140 outputs a baseband signal, the output 144 may be coupled to a baseband processor (shown in FIG. 2). In this example, the baseband processor may decode and/or demodulate the baseband signal to recover data and/or control information from the baseband signal.

For the example where the receive circuit 140 outputs an IF signal, the output 144 may be coupled to an IF circuit (not shown). In this example, the IF circuit may frequency downconvert the IF signal to obtain a baseband signal and output the baseband signal to a baseband processor.

FIG. 1B shows an example in which the LNA 130 and the receive circuit 140 are integrated on a chip 170. The chip 170 includes a pad 160 coupled to the input 132 of the LNA 130. In this example, the front-end circuit 125 is coupled between the antenna 110 and the pad 160. Thus, in this example, the input 132 of the LNA 130 is coupled to the front-end circuit 125 through the pad 160. For implementations where the front-end circuit 125 is omitted, the pad 160 may be coupled to the antenna 110 without the front-end circuit 125.

It is to be appreciated that, in other implementations, the LNA 130 and the receive circuit 140 may be integrated on separate chips. In these implementations, the chip that includes the LNA 130 may include the pad 160 coupled to the input 132 of the LNA 130.

FIG. 2 shows an exemplary implementation of the receive circuit 140 according to certain aspects. In this example, the receive circuit 140 includes a mixer 210, a baseband filter 220, and an analog-to-digital converter (ADC) 230.

In the example in FIG. 2, the mixer 210 has an input 212 coupled to the output 134 of the LNA 130, and an output 214. The baseband filter 220 has an input 222 coupled to the output 214 of the mixer 210, and an output 224. The ADC 230 has an input 232 coupled to the output 224 of the baseband filter 220, and an output 234. The output 234 of the ADC 230 may be coupled to an input 252 of a baseband processor 250, as shown in the example in FIG. 2.

The mixer 210 is configured to receive the amplified RF signal from the LNA 130 at the input 212, mix the RF signal with a local oscillator signal (labeled “LO”) to frequency downconvert the RF signal into a baseband signal, and output the baseband signal at the output 214. The baseband filter 220 may be configured to the pass the baseband signal to the input 232 of the ADC 230 while filtering out out-of-band signals. The ADC 230 is configured to receive the baseband signal at the input 232, convert the baseband signal into a digital signal, and output the digital signal at the output 234. For example, the ADC 230 may output the digital signal to the input 252 of the baseband processor 250 for baseband processing in the digital domain.

It is to be appreciated that the receive circuit 140 may include one or more additional circuits (not shown) in the receive path between the input 142 and the output 144 of the receive circuit 140.

An LNA may include inductors (e.g., to achieve high gain in a desired frequency band and/or impedance matching). However, inductors increase die area, are not easily portable to different technologies, and may result in unwanted magnetic coupling. As a result, next generation LNAs are moving towards inductor-less LNA designs.

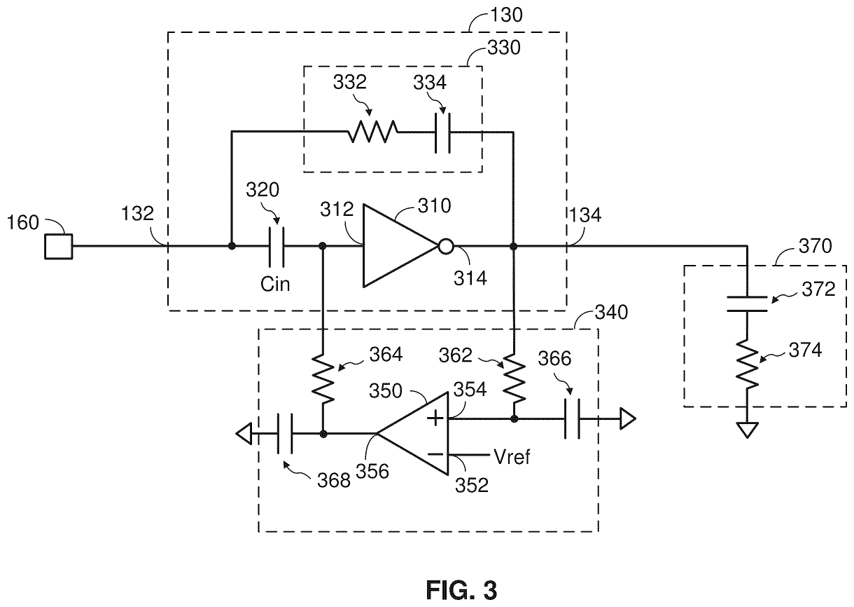

In this regard, FIG. 3 shows an example in which the LNA 130 is implemented with an inductor-less LNA according to certain aspects. In this example, the LNA 130 includes an inverter 310 and a coupling capacitor 320. The coupling capacitor 320 is coupled between the input 132 of the LNA 130 and the input 312 of the inverter 310, and the output 314 of the inverter 310 is coupled to the output 134 of the LNA 130. The coupling capacitor 320 is configured to AC couple the input 312 of the inverter 310 to the input 132 of the LNA 130. The inverter 310 may be implemented with a complementary inverter including a p-type metal-oxide-semiconductor (PMOS) transistor and an n-type metal-oxide-semiconductor (NMOS) transistor. In this example, the inverter 310 provides amplification for the LNA 130.

In certain aspects, the LNA 130 may be integrated on a chip (e.g., the chip 170). In the example shown in FIG. 3, the input 132 of the LNA 130 is coupled to the pad 160 on the chip. In some implementations, the input 132 of the LNA 130 may be coupled between one or more other elements and the pad 160 on the chip. The pad 160 is configured to couple the chip to an external component. For example, the pad 160 may be coupled to the front-end circuit 125 and/or the antenna 110 (e.g., via a transmission line). Thus, in this example, the input 132 of the LNA 130 may be coupled to the front-end circuit 125 and/or the antenna 110 through the pad 160. However, it is to be appreciated that the present disclosure is not limited to this example (e.g., such as the pad 316 coupled to an RFFE module including one or more additional LNAs and one or more filters and switches).

In the example in FIG. 3, a load 370 is coupled to the output 134 of the LNA 130. In this example, the load 370 includes a capacitor 372 and a resistor 374 coupled in series between the output 134 of the LNA 130 and ground. The load 370 models the load of the following stage (e.g., the load of the receive circuit 140).

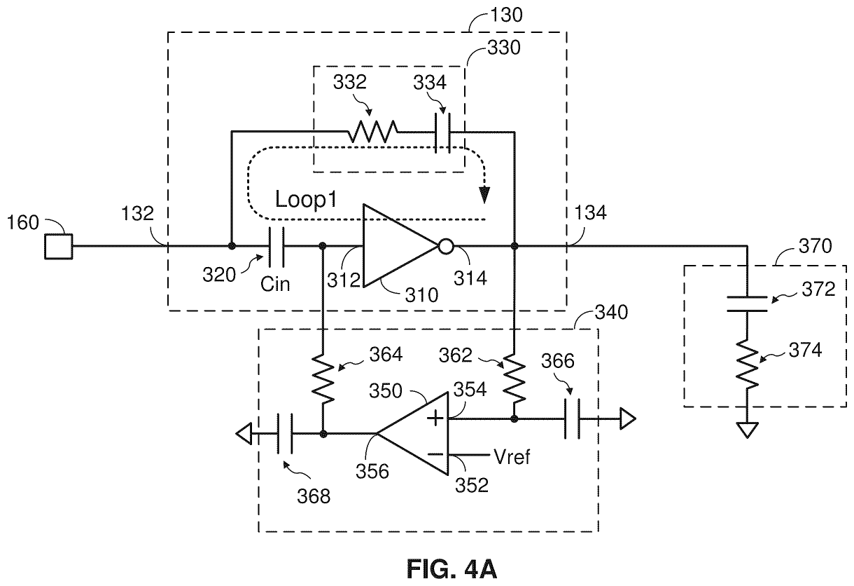

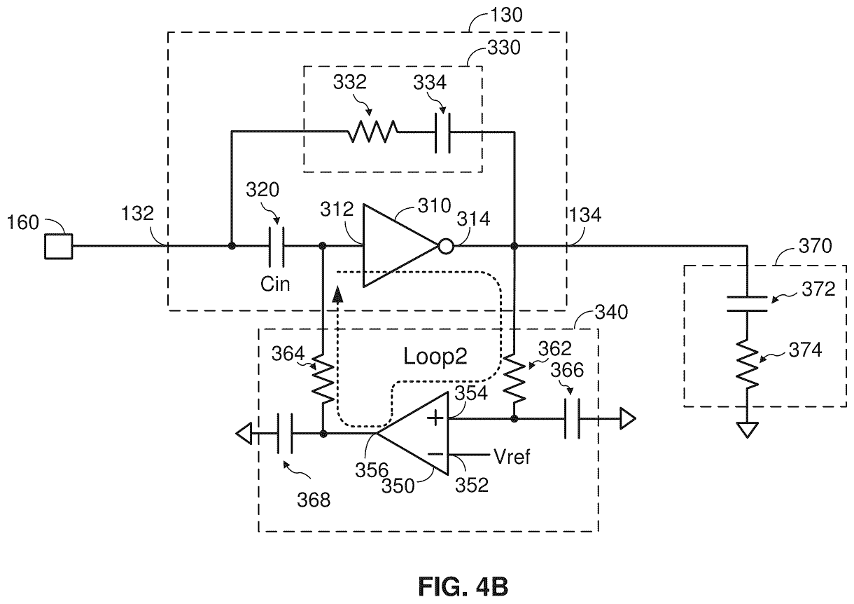

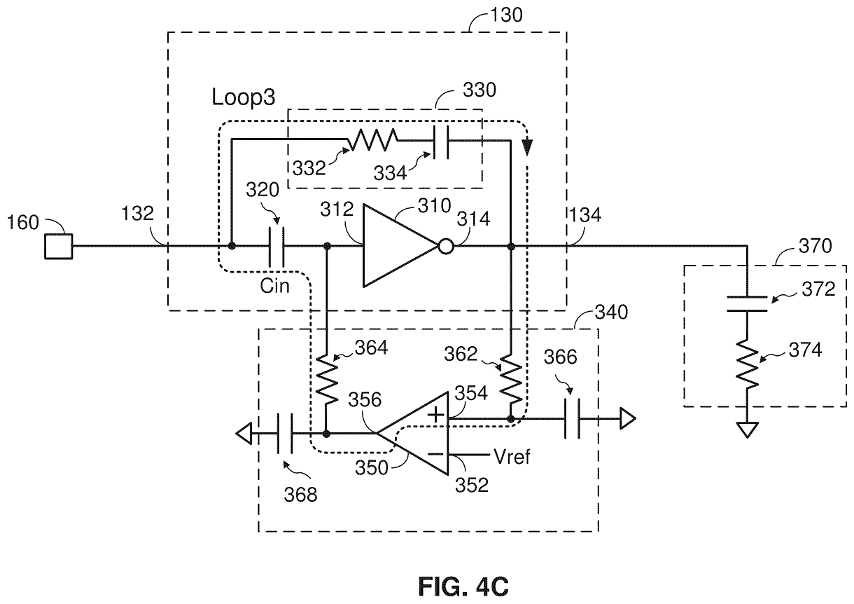

In the example in FIG. 3, the LNA 130 includes an RF feedback circuit 330 coupled between the output 134 and the input 132 of the LNA 130. In this example, the RF feedback circuit 330 includes a feedback resistor 332 and a feedback capacitor 334 coupled in series between the output 134 and the input 132 of the LNA 130. The feedback capacitor 334 passes RF signals while blocking DC voltages. In this example, the feedback resistor 332 provides resistive feedback that helps set the RF performance of the LNA 130 (e.g., RF gain of the LNA 130 and/or RF impedance matching). Referring to FIG. 4A, the RF feedback circuit 330 provides RF feedback loop (labeled “Loop1” in FIG. 4A) that defines the RF performance of the LNA 130 (e.g., RF gain and/or RF impedance matching).

For example, to the first order, the RF gain may be approximately proportional to the resistance of the feedback resistor 322 and the transconductance (i.e., gm) of the inverter 310 (which is set by the inverter bias point), and the input impedance may be approximately proportional to the resistance of the feedback resistor 322 and 1/gm. In this example, a desired RF performance (e.g., RF gain and input match) may be achieved by choosing the resistance of the feedback resistor 322 and the transconductance (i.e., gm) accordingly. A challenge with the LNA 130 is that, after the resistance of the feedback resistor 322 and the transconductance (i.e., gm) are chosen for RF performance, the LNA 130 may suffer from instability at low frequencies, as discussed further below.

Returning to FIG. 3, the input 312 of the inverter 310 is biased using a bias circuit 340 coupled between the output 134 of the LNA 130 and the input 312 of the inverter 310. In the example in FIG. 3, the bias circuit 340 includes an amplifier 350, a first resistor 362, a second resistor 364, a first capacitor 366, and a second capacitor 368. The amplifier 350 has a first input 352 (e.g., minus input) configured to receive a reference voltage Vref, a second input 354 (e.g., plus input), and an output 356.

The first resistor 362 is coupled between output 134 of the LNA 130 and the second input 354 of the amplifier 350, and the first capacitor 366 is coupled between the second input 354 of the amplifier 350 and ground (or some reference potential). The second resistor 364 is coupled between the output 356 of the amplifier 350 and the input 312 of the inverter 310, and the second capacitor 368 is coupled between the output 356 of the amplifier 350 and ground (or some reference potential).

In operation, the amplifier 350 senses the DC voltage at the output 134 of the LNA 130 through the first resistor 362, and adjusts the bias voltage at the input 312 of the inverter 310 in a direction that reduces the difference (i.e., error) between the DC voltage at the output 134 and the reference voltage Vref. As a result, the bias circuit 340 forces the DC voltage at the output 134 of the LNA 130 to be approximately equal to the reference voltage Vref. Thus, the output 134 of the LNA 130 may be set to a desired DC bias point by setting the reference voltage Vref accordingly. In one example, the reference voltage Vref may be approximately equal to Vdd/2 where Vdd is a supply voltage.

Referring to FIG. 4B, the bias circuit 340 provides a DC bias loop (labeled “Loop2”) that sets the DC bias point at the output 134 of the LNA to be approximately equal to the reference voltage Vref (e.g., Vdd/2). The bias loop is slow compared with the RF signal, which may have a frequency in the range of one GHz to several GHz. However, it is to be appreciated that the RF signal is not limited to this example.

Both the RF feedback loop (i.e., “Loop1”) and the bias loop (i.e., “Loop2”) are negative feedback loops. Together, the RF feedback loop (i.e., “Loop1”) and the bias loop (i.e., “Loop2”) form an unintended positive feedback loop (labeled “Loop3”), an example of which is shown in FIG. 4C. The positive feedback loop can produce a positive S11 parameter (i.e., S11>0 dB) at low frequencies (e.g., between 1 and 100 MHz) if the positive feedback loop is strong enough at low frequencies. The positive S11 parameter leads to low frequency instability.

The bias loop (i.e., “Loop2”) may have a high voltage gain at some internal nodes between 1 and 100 MHz. If any jammers create a beating tone around these frequencies and the bias loop experiences compression, the low frequency instability may become worse.

The low frequency stability may also be improved by coupling a shunt inductor to the input 132 of the LNA 130. The shunt inductor achieves low frequency stability by reducing the low frequency gain of the LNA 130, which weakens the positive feedback loop (i.e., “Loop3”). However, the shunt inductor increases die area and is prone to isolation concerns due to unwanted magnetic coupling.

The impedance Zcin of the coupling capacitor 320 may be high at low frequencies compared with the impedance Zcin of the coupling capacitor 320 at RF frequencies since the impedance of a capacitor increases as frequency goes down. The high impedance Zcin at low frequencies increases the strength of the positive feedback loop at low frequencies, which contributes to the low frequency instability discussed above.

To address the above, aspects of the present disclosure move the coupling capacitor 320 outside of the RF feedback loop, which also moves the coupling capacitor 320 outside of the positive feedback loop (i.e., “Loop 3”). Moving the coupling capacitor 320 outside of the positive feedback loop weakens the positive feedback loop at low frequencies, which improves low frequency stability. The above features and other features of the present disclosure are discussed further below.

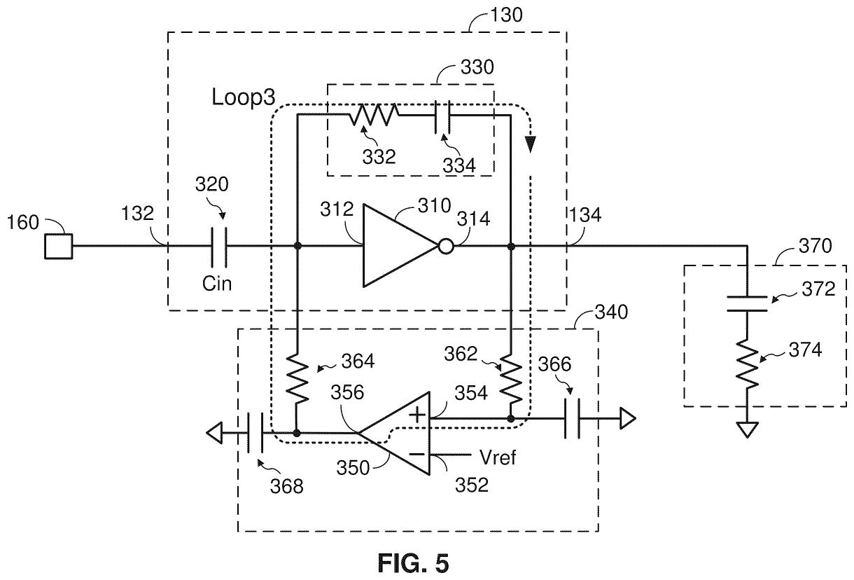

FIG. 5 shows an example of the LNA 130 in which the coupling capacitor 320 is moved outside of the RF feedback loop (i.e., “Loop1”). In this example, the RF feedback circuit 330 in the RF feedback loop is coupled between the output 314 of the inverter 310 and the input 312 of the inverter 310 with the coupling capacitor 320 located outside of the RF feedback loop. As shown in FIG. 5, moving the coupling capacitor 320 outside of the RF feedback loop (i.e., “Loop1”) moves the coupling capacitor 320 outside of the positive feedback loop (i.e., “Loop3”) formed by the RF feedback loop (i.e., “Loop1” in FIG. 4A) and the bias loop (i.e., “Loop2” in FIG. 4B). As a result, the impedance Zcin of the coupling capacitor 320 does not contribute to the strength of the positive feedback loop (i.e., “Loop3”). This weakens the positive feedback loop (i.e., “Loop3”) at low frequencies which helps prevents the low frequency instability discussed above.

In the example in FIG. 5, the coupling capacitor 320 is coupled between the pad 160 and the input 312 of the inverter 310 to AC couple RF signals at the pad 160 to the input of the inverter 310. As discussed above, the pad 160 may be coupled to the antenna 110 and/or the front-end circuit 125.

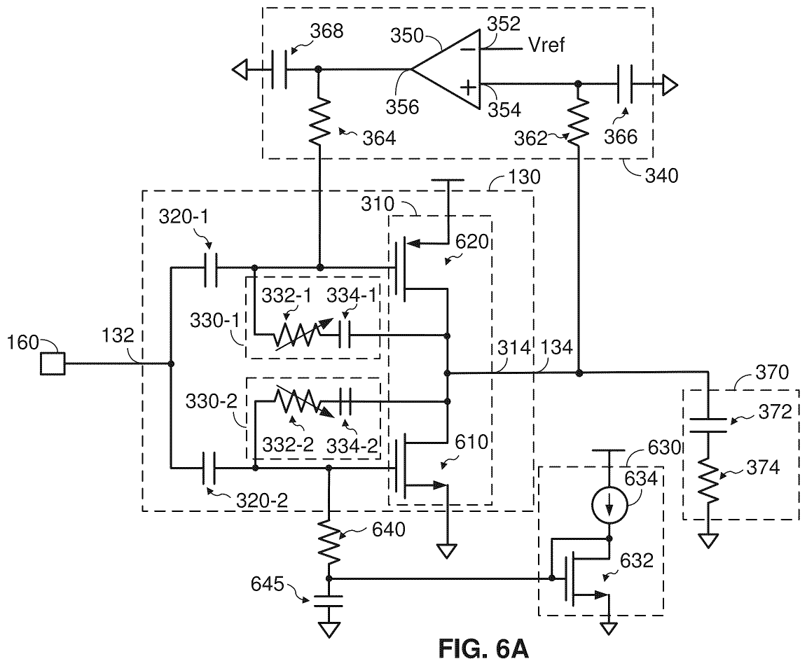

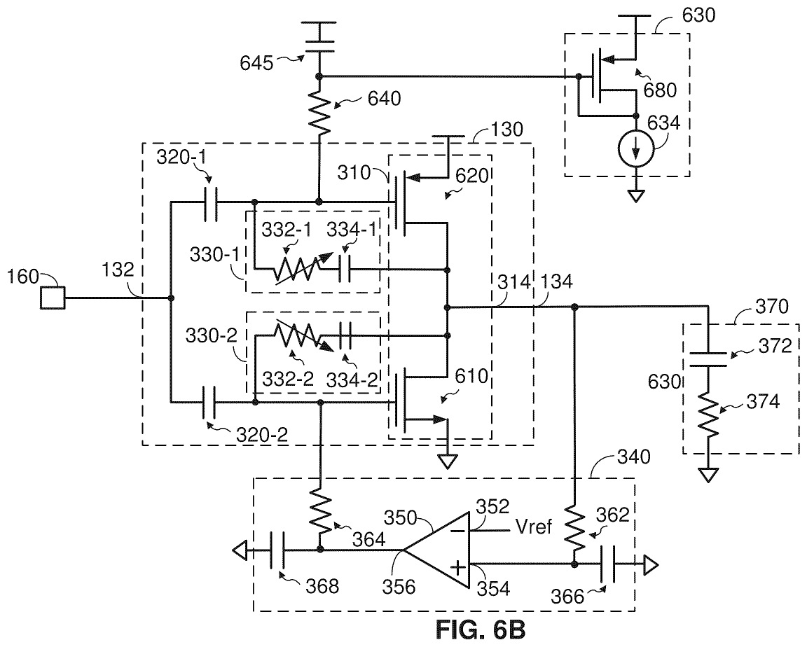

FIG. 6A shows an example in which the inverter 310 is implemented with a complementary inverter including a p-type metal-oxide-semiconductor (PMOS) transistor 620 and an n-type metal-oxide-semiconductor (NMOS) transistor 610. A PMOS transistor may also be referred to as a p-type field effect transistor (PFET) and an NMOS transistor may also be referred to as an n-type field effect transistor (NFET). In this example, the source of the PMOS transistor 620 is coupled to a supply rail, the source of the NMOS transistor 610 is coupled to ground (or some reference potential), and the drains of the PMOS transistor 620 and the NMOS transistor 610 are coupled to the output 134 of the LNA 130.

In the example in FIG. 6A, the gate of the PMOS transistor 620 is biased using the bias circuit 340, in which the bias circuit 340 is coupled between the output 314 of the inverter 310 and the gate of the PMOS transistor 620. In this example, the DC bias loop biases the gate of the PMOS transistor 620 to set the DC bias point at the output 134 of the LNA 130 to be approximately equal to the reference voltage Vref (e.g., Vdd/2).

In the example in FIG. 6A, the gate of the NMOS transistor 610 is biased using a current mirror 630. The current mirror 630 is coupled to the gate of the NMOS transistor 610 through a bias resistor 640. The current mirror 630 is configured to bias the gate of the NMOS transistor 610 to set the DC bias current of the inverter 310 based on a reference current. In this example, the current mirror 630 includes an NMOS transistor 632 and a reference current source 634 configured to generate the reference current. The gate and the drain of the NMOS transistor 632 are coupled together, and the source of the NMOS transistor 632 is coupled to ground (or some reference potential). The reference current source 634 is coupled to the drain of the NMOS transistor 632, and the gate of the NMOS transistor 632 is coupled to the gate of the NMOS transistor 610 through the bias resistor 640.

In some implementations, a shunt capacitor 645 is coupled between the gate of the NMOS transistor 632 and the ground, in which the combination of the shunt capacitor 645 and the bias resistor 640 provides a low pass filter that reduces noise from the current mirror 630.

In this example, the RF feedback circuit 330 is split into a first RF feedback circuit 330-1 and a second RF feedback circuit 330-2. The first RF feedback circuit 330-1 is coupled between the output 314 of the inverter 310 and the gate of the PMOS transistor 620 to provide a first RF feedback loop for the PMOS transistor 620. In the example in FIG. 6A, the first RF feedback circuit 330-1 includes a first feedback resistor 332-1 and a first feedback capacitor 334-1 coupled in series between the output 314 of the inverter 310 and the gate of the PMOS transistor 620. The first RF feedback loop and the bias loop form a positive feedback loop. However, the positive feedback loop is weakened by moving the coupling capacitor outside of the positive feedback loop, as discussed further below.

The second RF feedback circuit 330-2 is coupled between the output 314 of the inverter 310 and the gate of the NMOS transistor 610 to provide a second RF feedback loop for the NMOS transistor 610. In the example in FIG. 6A, the second RF feedback circuit 330-2 includes a second feedback resistor 332-2 and a second feedback capacitor 334-2 coupled in series between the output 314 of the inverter 310 and the gate of the NMOS transistor 610.

In this example, the first RF feedback loop and the second RF feedback loop help set the RF performance of the LNA 130 (e.g., RF gain of the LNA 130 and/or RF impedance matching). In certain aspects, the first feedback resistor 332-1 is implemented with a first variable resistor and the second feedback resistor 332-2 is implemented with a second variable resistor to provide tunability of the RF gain by tuning the resistances of the feedback resistor 332-1 and the second feedback resistor 332-2. A variable resistor may be implemented with a network of resistors and switches

In this example, the coupling capacitor 320 is split into a first coupling capacitor 320-1 and a second coupling capacitor 320-2. The first coupling capacitor 320-1 is coupled between the gate of the PMOS transistor 620 and the input 132, and AC couples an RF signal from the input 132 to the gate of the PMOS transistor 620. The first coupling capacitor 320-1 is located outside of the first RF feedback loop. As a result, the first coupling capacitor 320-1 is located outside of the positive feedback loop formed by the first RF feedback loop and the bias loop. As a result, the coupling capacitor 320-1 does not contribute to the strength of the positive feedback loop, thereby improving low frequency stability.

The second coupling capacitor 320-2 is coupled between the gate of the NMOS transistor 610 and the input 132, and AC couples an RF signal from the input 132 to the gate of the NMOS transistor 610. The second coupling capacitor 320-2 is located outside of the second RF feedback loop.

In this example, splitting the RF feedback loop into two RF feedback loops (i.e., the first RF feedback loop and the second RF feedback loop) allows the gate of the PMOS transistor 620 and the gate of the NMOS transistor 610 to be separately biased while keeping the coupling capacitors 320-1 and 320-2 outside of the RF feedback loops for improved low frequency stability.

In the example shown in FIG. 6A, the bias circuit 340 is coupled to the gate of the PMOS transistor 620 and the current mirror 630 is coupled to the gate of the NMOS transistor 610. However, it is to be appreciated that the present disclosure is not limited to this example. In this regard, FIG. 6B shows an example where the bias circuit 340 is coupled to the gate of the NMOS transistor 610 and the current mirror 630 is coupled to the gate of the PMOS transistor 620.

In the example in FIG. 6B, the output 356 of the amplifier 350 is coupled to the gate of the NMOS transistor 610 through the second resistor 364. In this example, the DC bias loop biases the gate of the NMOS transistor 610 to set the DC bias point at the output 134 of the LNA 130 to be approximately equal to the reference voltage Vref (e.g., Vdd/2).

In the example in FIG. 6B, the current mirror 630 includes a PMOS transistor 680 in place of the NMOS transistor 632 in FIG. 6A. In this example, the gate and the drain of the PMOS transistor 680 are coupled together, and the source of the PMOS transistor 680 is coupled to the supply rail. The reference current source 634 is coupled to the drain of the PMOS transistor 680, and the gate of the PMOS transistor 680 is coupled to the gate of the PMOS transistor 620 through the bias resistor 640. In this example, the shunt capacitor 645 may be coupled between the gate of the PMOS transistor 680 and the supply rail (shown in the example in FIG. 6B) or between the gate of the PMOS transistor 680 and ground.

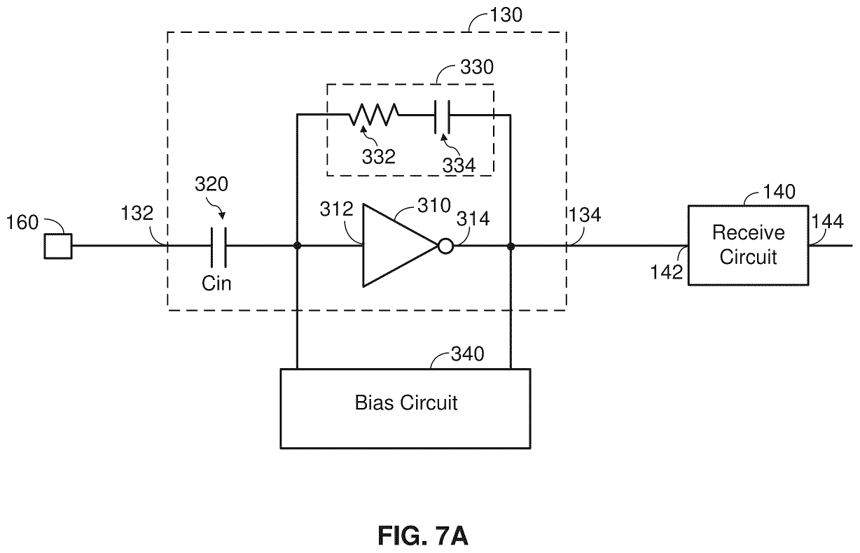

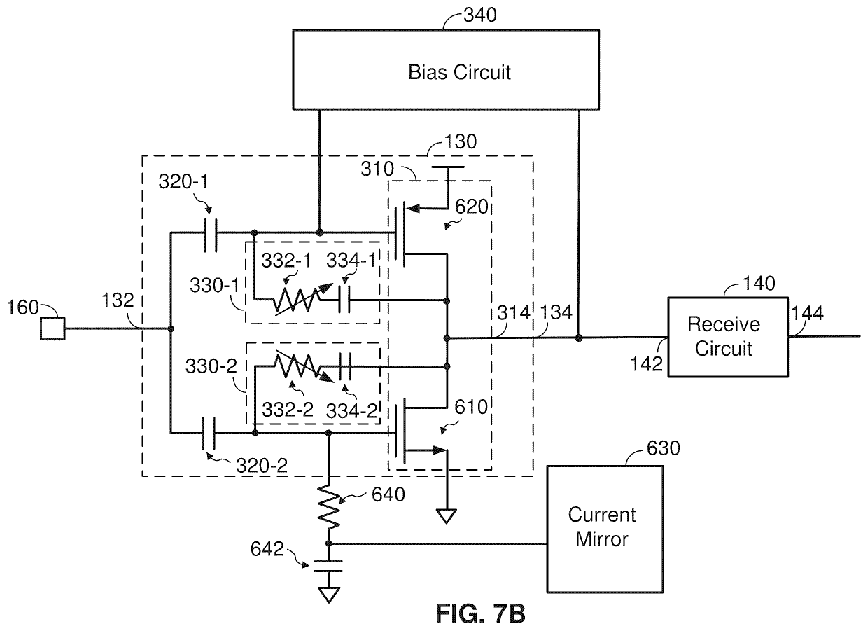

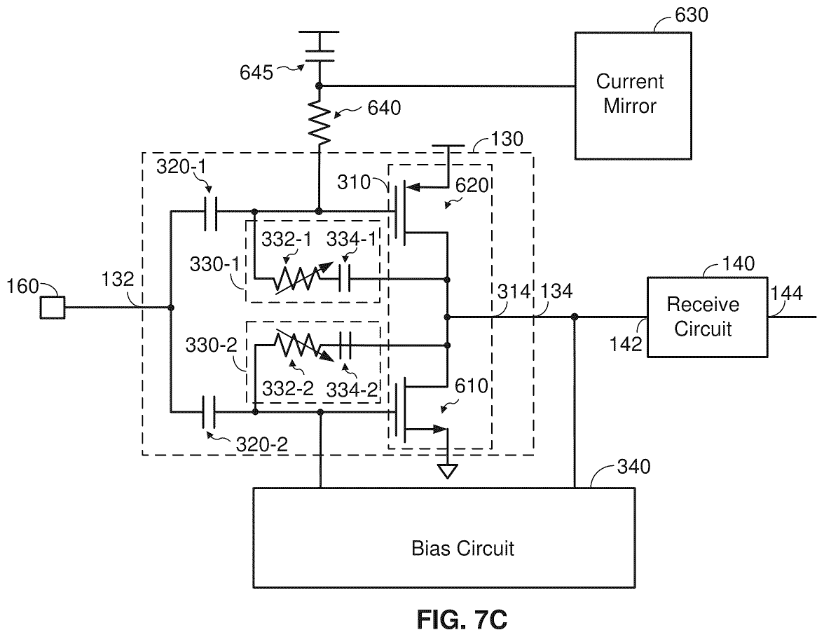

FIG. 7A shows an example in which the output 134 of the exemplary LNA 130 of FIG. 5 is coupled the input 142 of the receive circuit 140, FIG. 7B shows an example in which the output 134 of the exemplary LNA 130 of FIG. 6A is coupled the input 142 of the receive circuit 140, and FIG. 7C shows an example in which the output 134 of the exemplary LNA 130 of FIG. 6B is coupled the input 142 of the receive circuit 140. In these examples, the exemplary load 370 (shown in FIGS. 5, 6A, and 6B) may model the load of the receive circuit 140. The receive circuit 140 may include the mixer 210, the baseband filter 220, the ADC 230, and/or one or more other circuits.

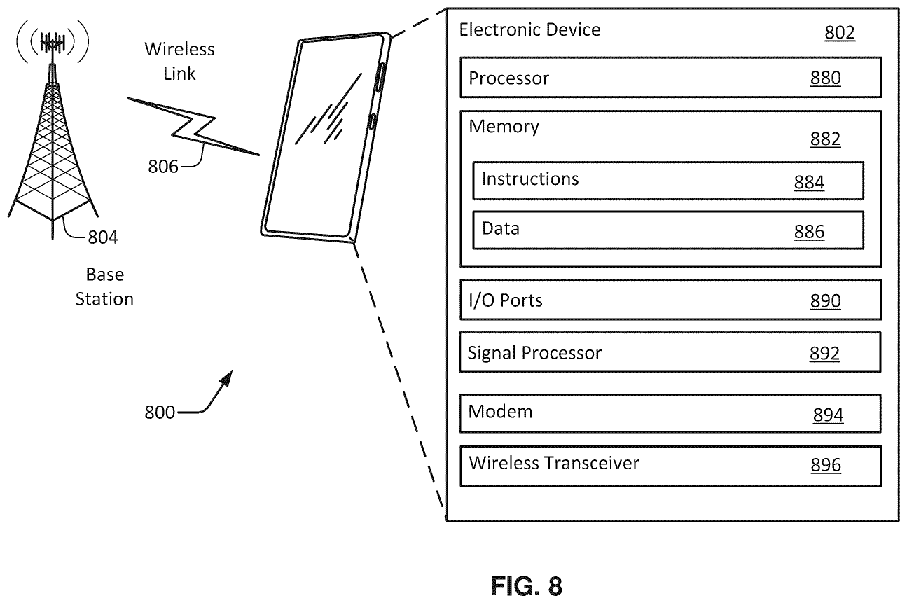

FIG. 8 is a diagram of an environment 800 that includes a wireless device 802 and a base station 804. In the environment 800, the wireless device 802 communicates with the base station 804 via a wireless link 806. As shown, the wireless device 802 is depicted as a smart phone. However, it is to be understood that the wireless device 802 may be implemented as any suitable wireless device, such as a cellular base station, a broadband router, an access point, a cellular or mobile phone, a gaming device, a navigation device, a media device, a laptop computer, a desktop computer, a tablet computer, a server computer, a network-attached storage (NAS) device, a smart appliance, a vehicle-based communication system, an Internet of Things (IoT) device, a sensor or security device, an asset tracker, and so forth.

The base station 804 communicates with the wireless device 802 via the wireless link 806, which may be implemented as any suitable type of wireless link. Although depicted as a base station tower of a cellular radio network, the base station 804 may represent or be implemented as another device, such as a satellite, a terrestrial broadcast tower, an access point, a peer-to-peer device, a mesh network node, and so forth. The wireless link 806 may include a downlink of data and/or control information communicated from the base station 804 to the wireless device 802 and an uplink of other data and/or control information communicated from the wireless device 802 to the base station 804. The wireless link 806 may be implemented using any suitable communication protocol or standard, such as 3rd Generation Partnership Project Long-Term Evolution (3GPP LTE, 3GPP NR 5G), IEEE 802.77, IEEE 802.77, Bluetooth™, and so forth.

The wireless device 802 includes a processor 880 and a memory 882. The memory 882 may be or form a portion of a computer readable storage medium. The processor 880 may include any type of processor, such as an application processor or a multi-core processor, that is configured to execute processor-executable instructions stored in the memory 882. The memory 882 may include any suitable type of data storage media, such as a volatile memory (e.g., random access memory (RAM)), a non-volatile memory (e.g., Flash memory), an optical media, a magnetic media (e.g., disk or tape), or any combination thereof. In the context of this disclosure, the memory 882 may store instructions 884, data 886, and other information of the wireless device 802.

The wireless device 802 may also include input/output (I/O) ports 890. The I/O ports 890 enable data exchanges or interaction with other devices, networks, or users or between components of the wireless device 802.

The wireless device 802 may further include a signal processor (SP) 892 (e.g., such as a digital signal processor (DSP)). The signal processor 892 may function similar to the processor 880 and may be capable of executing instructions and/or processing information in conjunction with the memory 882.

For communication purposes, the wireless device 802 also includes a modem 894 (e.g., the baseband processor 250), a wireless transceiver 896, and one or more antennas (e.g., the antenna 110). The wireless transceiver 896 may include the LNA 130 and the receive circuit 140 discussed above. The wireless transceiver 896 provides connectivity to respective networks (e.g., the base station 804) and other wireless devices connected therewith using RF signals. The wireless transceiver 896 may facilitate communication over any suitable type of wireless network, such as a wireless local area network (LAN) (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).
1. A system for wireless communications, comprising:
a low-noise amplifier (LNA), the LNA comprising:
   an inverter;
   a radio frequency (RF) feedback circuit coupled between an output of the inverter and an input of the inverter to provide an RF feedback loop; and
   a coupling capacitor coupled between an input of the LNA and the input of the inverter, wherein the coupling capacitor is located outside of the RF feedback loop; and
   a bias circuit coupled between the output of the inverter and the input of the inverter.
2. The system of clause 1, wherein the RF feedback circuit comprises a feedback resistor and a feedback capacitor coupled in series between the output of the inverter and the input of the inverter.
3. The system of clause 1 or 2, wherein the system is integrated on a chip including a pad, and the coupling capacitor is coupled between the input of the inverter and the pad.
4. The system of clause 3, wherein the pad is coupled to an antenna.
5. The system of clause 3, wherein the pad is coupled to an RF front-end (RFFE) circuit.
6. The system of clause 5, wherein the RFFE circuit includes a filter.
7. The system of any one of clauses 1 to 6, further comprising a receive circuit coupled to the output of the inverter, the receive circuit including a mixer.
8. The system of any one of clauses 1 to 7, wherein the bias circuit comprises an amplifier having a first input configured to receive a reference voltage, a second input coupled to the output of the inverter, and an output coupled to the input of the inverter.
9. A system for wireless communications, comprising:
a low-noise amplifier (LNA), the LNA comprising:
   an inverter including a p-type metal-oxide-semiconductor (PMOS) transistor and an n-type metal-oxide-semiconductor (NMOS) transistor;
   a first radio frequency (RF) feedback circuit coupled between an output of the inverter and a gate of the PMOS transistor to provide a first RF feedback loop;
   a second RF feedback circuit coupled between the output of the inverter and a gate of the NMOS transistor to provide a second RF feedback loop;
   a first coupling capacitor coupled between an input of the LNA and the gate of the PMOS transistor, wherein the first coupling capacitor is located outside of the first RF feedback loop; and
   a second coupling capacitor coupled between the input of the LNA and the gate of the NMOS transistor, wherein the first coupling capacitor is located outside of the second RF feedback loop; and
a bias circuit coupled between the output of the inverter and the gate of the PMOS transistor or coupled between the output of the inverter and the gate of the NMOS transistor.
10. The system of clause 9, wherein the first RF feedback circuit comprises a first feedback resistor and a first feedback capacitor coupled in series between the output of the inverter and the gate of the PMOS transistor.
11. The system of clause 10, wherein the second RF feedback circuit comprises a second feedback resistor and a second feedback capacitor coupled in series between the output of the inverter and the gate of the NMOS transistor.
12. The system of clause 11, wherein the first feedback resistor comprises a first variable resistor and the second feedback resistor comprises a second variable resistor.
13. The system of any one of clauses 9 to 12, wherein:
a source of the PMOS transistor is coupled to a supply rail;
a drain of the PMOS transistor is coupled to the output of the inverter;
a drain of the NMOS transistor is coupled to the output of the inverter; and
a source of the NMOS transistor is coupled to a ground.
14. The system of any one of clauses 9 to 13, wherein the system is integrated on a chip including a pad, the first coupling capacitor is coupled between the pad and the gate of the PMOS transistor, and the second coupling capacitor is coupled between the pad and the gate of the NMOS transistor.
15. The system of clause 14, wherein the pad is coupled to an antenna.
16. The system of clause 14, wherein the pad is coupled to an RF front-end (RFFE) circuit.
17. The system of clause 16, wherein the RFFE circuit includes a filter.
18. The system of any one of clauses 9 to 17, further comprising a receive circuit coupled to the output of the inverter, the receive circuit including a mixer.
19. The system of any one of clauses 9 to 18, wherein the bias circuit comprises an amplifier having a first input configured to receive a reference voltage, a second input coupled to the output of the inverter, and an output coupled to the gate of the PMOS transistor.
20. The system of clause 19, further comprising a current mirror coupled to the gate of the NMOS transistor, wherein the current mirror is configured to bias the gate of the NMOS transistor based on a reference current.
21. The system of any one of clauses 9 to 18, wherein the bias circuit comprises an amplifier having a first input configured to receive a reference voltage, a second input coupled to the output of the inverter, and an output coupled to the gate of the NMOS transistor.
22. The system of clause 21, further comprising a current mirror coupled to the gate of the PMOS transistor, wherein the current mirror is configured to bias the gate of the PMOS transistor based on a reference current.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a direct current (DC) ground or an alternating current (AC) ground, and thus the term “ground” covers both possibilities. An AC ground may be provided by a DC voltage.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A system for wireless communications, comprising:
a low-noise amplifier (LNA), the LNA comprising:
an inverter;
a radio frequency (RF) feedback circuit coupled between an output of the inverter and an input of the inverter to provide an RF feedback loop; and
a coupling capacitor coupled between an input of the LNA and the input of the inverter, wherein the coupling capacitor is located outside of the RF feedback loop; and
a bias circuit coupled between the output of the inverter and the input of the inverter.

2. The system of claim 1, wherein the RF feedback circuit comprises a feedback resistor and a feedback capacitor coupled in series between the output of the inverter and the input of the inverter.

3. The system of claim 1, wherein the system is integrated on a chip including a pad, and the coupling capacitor is coupled between the input of the inverter and the pad.

4. The system of claim 3, wherein the pad is coupled to an antenna.

5. The system of claim 3, wherein the pad is coupled to an RF front-end (RFFE) circuit.

6. The system of claim 5, wherein the RFFE circuit includes a filter.

7. The system of claim 1, further comprising a receive circuit coupled to the output of the inverter, the receive circuit including a mixer.

8. The system of claim 1, wherein the bias circuit comprises an amplifier having a first input configured to receive a reference voltage, a second input coupled to the output of the inverter, and an output coupled to the input of the inverter.

9. A system for wireless communications, comprising:
a low-noise amplifier (LNA), the LNA comprising:
an inverter including a p-type metal-oxide-semiconductor (PMOS) transistor and an n-type metal-oxide-semiconductor (NMOS) transistor;
a first radio frequency (RF) feedback circuit coupled between an output of the inverter and a gate of the PMOS transistor to provide a first RF feedback loop;
a second RF feedback circuit coupled between the output of the inverter and a gate of the NMOS transistor to provide a second RF feedback loop;
a first coupling capacitor coupled between an input of the LNA and the gate of the PMOS transistor, wherein the first coupling capacitor is located outside of the first RF feedback loop; and
a second coupling capacitor coupled between the input of the LNA and the gate of the NMOS transistor, wherein the first coupling capacitor is located outside of the second RF feedback loop; and
a bias circuit coupled between the output of the inverter and the gate of the PMOS transistor or coupled between the output of the inverter and the gate of the NMOS transistor.

10. The system of claim 9, wherein the first RF feedback circuit comprises a first feedback resistor and a first feedback capacitor coupled in series between the output of the inverter and the gate of the PMOS transistor.

11. The system of claim 10, wherein the second RF feedback circuit comprises a second feedback resistor and a second feedback capacitor coupled in series between the output of the inverter and the gate of the NMOS transistor.

12. The system of claim 11, wherein the first feedback resistor comprises a first variable resistor and the second feedback resistor comprises a second variable resistor.

13. The system of claim 9, wherein:
a source of the PMOS transistor is coupled to a supply rail;
a drain of the PMOS transistor is coupled to the output of the inverter;
a drain of the NMOS transistor is coupled to the output of the inverter; and
a source of the NMOS transistor is coupled to a ground.

14. The system of claim 9, wherein the system is integrated on a chip including a pad, the first coupling capacitor is coupled between the pad and the gate of the PMOS transistor, and the second coupling capacitor is coupled between the pad and the gate of the NMOS transistor.

15. The system of claim 14, wherein the pad is coupled to an RF front-end (RFFE) circuit.

16. The system of claim 9, further comprising a receive circuit coupled to the output of the inverter, the receive circuit including a mixer.

17. The system of claim 9, wherein the bias circuit comprises an amplifier having a first input configured to receive a reference voltage, a second input coupled to the output of the inverter, and an output coupled to the gate of the PMOS transistor.

18. The system of claim 17, further comprising a current mirror coupled to the gate of the NMOS transistor, wherein the current mirror is configured to bias the gate of the NMOS transistor based on a reference current.

19. The system of claim 9, wherein the bias circuit comprises an amplifier having a first input configured to receive a reference voltage, a second input coupled to the output of the inverter, and an output coupled to the gate of the NMOS transistor.

20. The system of claim 19, further comprising a current mirror coupled to the gate of the PMOS transistor, wherein the current mirror is configured to bias the gate of the PMOS transistor based on a reference current.
